(19) United States
(12) Patent Application Publication
(10) Pub. No.: US 2025/0046567 A1
(43) Pub. Date: Feb. 6, 2025

(54) Ion Milling Device

(71) Applicant: Hitachi High-Tech Corporation, Minato-ku, Tokyo (JP)

(72) Inventors: Shota AIDA, Tokyo (JP); Hisayuki TAKASU, Tokyo (JP); Kento HORINOUCHI, Tokyo (JP)

(21) Appl. No.: 18/716,990

(22) PCT Filed: Dec. 14, 2021
(86) PCT No.: PCT/JP2021/045995

§ 371 Date: Jun. 6, 2024

(51) Int. Cl. H01J 37/20; H01J 37/09; H01J 37/22; H01J 37/304; H01J 37/305

(52) U.S. Cl. CPC H01J 37/20; H01J 37/09; H01J 37/22; H01J 37/3045; H01J 37/305; H01J 2237/20214

(57) ABSTRACT

An ion milling device includes: an ion source 101 configured to emit an ion beam; a sample stage 102 configured to hold a sample 105; a shielding plate 106 configured to shield the sample from the ion beam and disposed such that an end surface P₂ thereof and an end surface P₁ serving as a processing surface of the sample are aligned with each other; a sample stage drive mechanism 103 configured to rotate the sample stage with a boundary between the end surface of the shielding plate and the end surface of the sample as a rotation axis R; and a control unit 109. A relative position between the ion source and the sample stage is adjusted such that a central axis B of the ion beam intersects the rotation axis. The control unit rotates the sample stage about the rotation axis using the sample stage drive mechanism until a sample protrusion amount at which the sample protrudes from the shielding plate as viewed from the ion source reaches a predetermined magnitude, and thereafter performs milling on the sample by irradiating the sample with the ion beam from the ion source.

### TECHNICAL FIELD

The present invention relates to an ion milling device.

### BACKGROUND ART

An ion milling device is a device that can irradiate a sample (for example, a metal, a semiconductor, glass, or ceramics), which is an object to be observed with an electron microscope, with an unfocused ion beam, remove atoms on a surface of the sample by a sputtering phenomenon, polish the surface of the sample with no stress, and expose an internal structure of the sample. By the ion beam irradiation, the polished surface of the sample and the exposed internal structure of the sample become observation surfaces of a scanning electron microscope or a transmission electron microscope.

When exposing the inner structure of the sample by the ion milling device, the sample is brought into close contact with a shielding plate and is caused to protrude from the shielding plate by an amount (in a range of several μm to several hundred μm) which is desired to be removed, and the sample of the protrusion amount is processed by the ion beam. In cross-section processing of the sample by such an ion milling device, in order to make the sample protrusion amount with respect to the shielding plate constant, it is common to apply the ion beam perpendicularly to a processing surface of the sample protruding from the shielding plate.

On the other hand, Patent Literature 1 discloses an example in which, in cross-section processing by an ion milling device, a sample is tilted in a direction in which a sample protrusion amount is changed. When the sample is irradiated with an ion beam, formation of an amorphous layer and a sputtering phenomenon occur in a region shielded by the shielding plate due to scattering of the ion beam into an inner portion of the sample. Accordingly, a range of about several μm from a surface along the shielding plate is processed in an overhang shape. Therefore, as disclosed in PTL 1, the sample and the shielding plate are inclined with respect to the ion beam in a direction in which the sample is masked by the shielding plate.

### CITATION LIST

### Patent Literature

PTL 1: WO2018/029778

### SUMMARY OF INVENTION

### Technical Problem

Among samples processed by an ion milling device, there is a sample that suffers thermal damage such as paper and a polymeric material. Indirect cooling of a sample by liquid nitrogen is known as a method of reducing thermal damage. However, for a sample having a relatively high glass transition point (0° C. or higher), a cooling temperature required is extremely low, which makes it difficult to apply the method. Even if the indirect cooling of the sample is possible, when there is a large discrepancy in physical property (for example, a heat transfer coefficient, a linear expansion coefficient) between the shielding plate and the sample, a gap may be generated between the shielding plate and the sample by the indirect cooling of the sample, leading to a deviation from a protrusion amount set in advance. In this case, since an irradiation region of the ion beam is changed, a target processing result is not obtained.

In order to avoid the influence on a processed shape exerted by the thermal damage or cooling of the sample due to the ion beam, it is necessary to reduce the sample protrusion amount of the sample with respect to the shielding plate to reduce the irradiation region of the ion beam on the sample and it is necessary to restrict application of heat to the sample caused by the ion beam. However, if the protrusion amount of the sample with respect to the shielding plate is reduced, it may be difficult to perform the cross-section processing by the ion milling device depending on a position of the internal structure of the sample to be exposed.

### Solution to Problem

An ion milling device according to an embodiment of the invention includes: an ion source configured to emit an ion beam; a sample stage configured to hold a sample; a shielding plate configured to shield the sample from the ion beam and disposed such that an end surface thereof and an end surface serving as a processing surface of the sample are aligned with each other; a sample stage drive mechanism configured to rotate the sample stage with a boundary between the end surface of the shielding plate and the end surface of the sample as a rotation axis; and a control unit. A relative position between the ion source and the sample stage is adjusted such that a central axis of the ion beam intersects the rotation axis. The control unit rotates the sample stage about the rotation axis using the sample stage drive mechanism until a sample protrusion amount at which the sample protrudes from the shielding plate as viewed from the ion source reaches a predetermined magnitude, and thereafter performs milling on the sample by irradiating the sample with the ion beam from the ion source.

### Advantageous Effects of Invention

It is possible to perform cross-section processing of a sample with high throughput while restricting heat application to a sample caused by milling by an ion beam. Other problems and novel features will become apparent from description of the present specification and the accompanying drawings.

### BRIEF DESCRIPTION OF DRAWINGS

FIG. 1 is a configuration example (schematic diagram) of an ion milling device according to Embodiment 1.

FIG. 2 is a schematic diagram illustrating an ion source and a power supply circuit configured to apply a control voltage to the ion source.

FIG. 3A is a diagram illustrating rotation control of a sample stage in cross-section processing.

FIG. 3B is a diagram illustrating the rotation control of the sample stage in the cross-section processing.

FIG. 3C is a diagram illustrating the rotation control of the sample stage in the cross-section processing.

FIG. 4 is a flowchart of cross-section processing of a sample according to Embodiment 1.

FIG. 5 is a configuration example (schematic diagram) of an ion milling device according to Embodiment 2.

FIG. 6 is a flowchart of cross-section processing of a sample according to Embodiment 2.

### DESCRIPTION OF EMBODIMENTS

Hereinafter, embodiments of the invention will be described with reference to the drawings.

### Embodiment 1

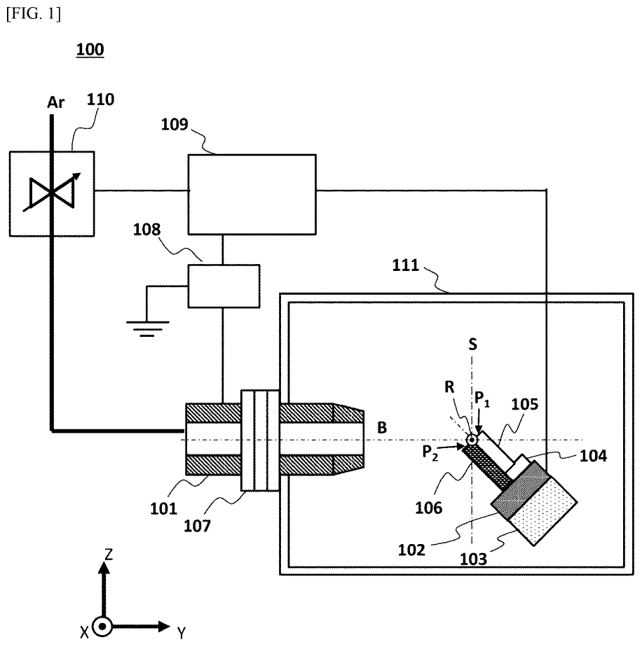

FIG. 1 is a schematic diagram illustrating, from a side, main parts of an ion milling device 100 according to Embodiment 1. In FIG. 1, a vertical direction is indicated as a Z direction. The ion milling device 100 includes, as main components, an ion source 101, a sample stage 102, a sample stage drive mechanism 103, a sample support 104 on which a sample 105 is to be placed, a shielding plate 106, an alignment mechanism 107, a high-voltage power supply 108, a control unit 109, a supply gas control unit 110, and a sample chamber 111.

The ion milling device 100 is used as a pretreatment device for observing a surface or a cross-section of a sample with a scanning electron microscope or a transmission electron microscope. An ion source for such a pretreatment device often adopts a Penning system, which is effective for downsizing a structure. Also in the embodiment, the ion source 101 adopts a Penning system, and an unfocused ion beam is emitted from the ion source 101 toward the sample 105. The control unit 109 adjusts a voltage applied from the high-voltage power supply 108 to an internal electrode of the ion source 101 and a flow rate of an argon gas supplied from the supply gas control unit 110, thereby controlling the output of the ion beam emitted from the ion source 101.

The sample 105 is attached to the sample support 104 such that an end surface P₁ as a processing surface of the sample 105 and an end surface P₂ of the shielding plate 106 are aligned with each other, and is held on the sample stage 102. A boundary between the end surface P₁ and the end surface P₂ serves as a rotation axis R, and the sample stage drive mechanism 103 rotates the sample stage 102 about the rotation axis R extending in an X direction. The sample stage drive mechanism 103 swings the sample stage 102 in a predetermined angular range about a swing axis S extending in the Z direction. Since the sample 105 is swung about the swing axis S in a predetermined angular range, an intensity of the ion beam applied to the processing surface of the sample 105 can be averaged.

A relative position between the ion source 101 and the sample stage 102 is adjusted such that a central axis B of the ion beam emitted from the ion source 101, the swing axis S, and the rotation axis R intersect at one point. In the configuration example in FIG. 1, the position of the ion source 101 is adjusted by using the alignment mechanism 107.

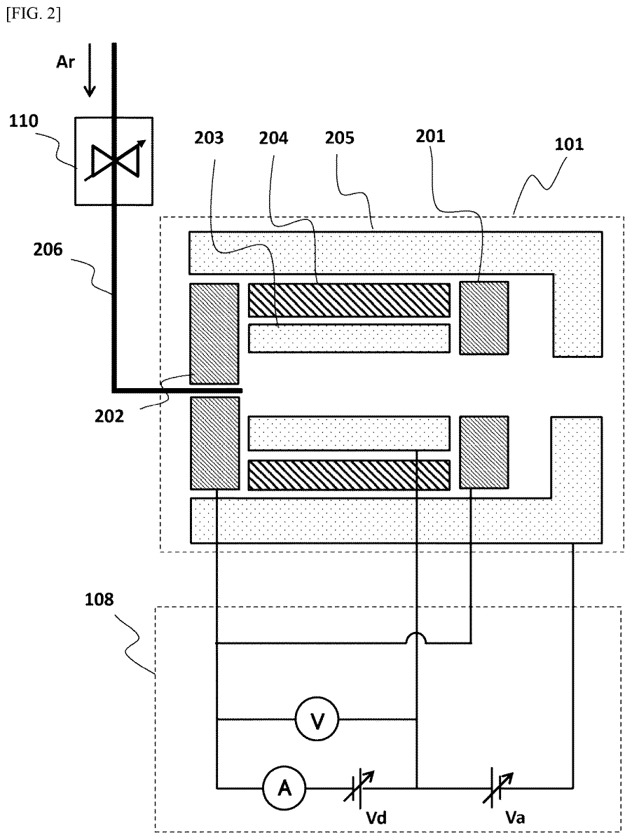

FIG. 2 is a schematic diagram illustrating the ion source 101 adopting the Penning system and a power supply circuit configured to apply a control voltage to electrode components of the ion source 101. The power supply circuit is a part of the high-voltage power supply 108.

The ion source 101 includes a first cathode 201, a second cathode 202, an anode 203, a permanent magnet 204, an acceleration electrode 205, and gas piping 206. In order to generate an ion beam, an argon gas is injected into the ion source 101 through the gas piping 206. In the ion source 101, the first cathode 201 and the second cathode 202 having the same potential are disposed facing each other, and the anode 203 is disposed between the first cathode 201 and the second cathode 202. When a discharge voltage Vd from the high-voltage power supply 108 is applied between the cathodes 201 and 202 and the anode 203, electrons are generated. The electrons are retained by the permanent magnet 204 disposed in the ion source 101 and collide with the argon gas injected from the gas piping 206 to generate argon ions. An acceleration voltage Va from the high-voltage power supply 108 is applied between the anode 203 and the acceleration electrode 205, and the generated argon ions are attracted to the acceleration electrode 205 and emitted as an ion beam.

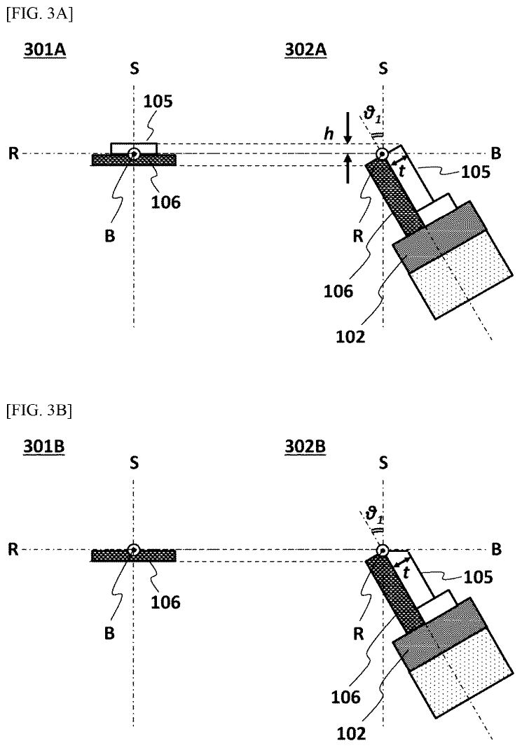

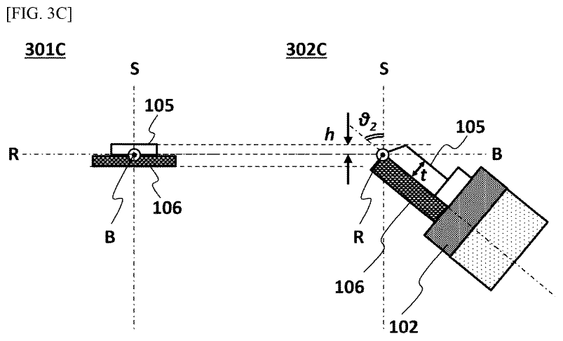

The rotation control of the sample stage in the cross-section processing will be described with reference to FIGS. 3A to 3C. FIG. 3A illustrates a front view 301A of the sample 105 and the shielding plate 106 as viewed from the ion source 101, and a side view 302A of the sample 105 and the shielding plate 106 as viewed from the same direction as in FIG. 1. When the sample stage 102 is rotated about the rotation axis R by a rotation angle θ₁, a sample protrusion amount h, which is the amount of the sample 105 protruding from the shielding plate 106 as viewed from the ion source 101, is expressed by Equation 1 in which t is a thickness of the sample 105.

$$h = t \times sin {θ}_{1} \qquad ( 1 )$$

In this state, by irradiating the sample 105 with the ion beam from the ion source 101, a portion of the sample 105 protruding from the shielding plate 106 as viewed from the ion source 101 is removed. A state in which the cross-section processing in this state is completed is illustrated in FIG. 3B. Similarly to FIG. 3A, a front view 301B and a side view 302B are illustrated in a corresponding manner. Since the protruding portion of the sample 105 is removed, the sample 105 cannot be seen in the front view 301B.

In order to expose the cross section of the sample 105 existing further inside, the sample stage 102 is further rotated about the rotation axis R. FIG. 3C illustrates a state in which the sample stage 102 is rotated about the rotation axis R by a rotation angle θ₂. Similarly to FIG. 3A, a front view 301C and a side view 302C are illustrated in a corresponding manner. The rotation angle θ₂ at this time is expressed by Equation 2.

$${θ}_{2} = arc sin ( h / t ) \qquad ( 2 )$$

In this state, by irradiating the sample 105 with the ion beam from the ion source 101, a portion of the sample 105 protruding from the shielding plate 106 as viewed from the ion source 101 is removed. Further, when exposing the cross section of the sample 105 existing further inside, the rotation of the sample stage 102 about the rotation axis R and milling by the ion beam are repeated.

Here, the larger the sample protrusion amount h is, the wider the irradiation range of the ion beam on the sample 105 is, and the influence of heat application on the sample 105 increases accordingly. For this reason, the sample protrusion amount h set before the sample processing is set to such an extent that the sample 105 is not affected by the heat from the ion beam, for example, about several μm to ten-odd μm. In exposing the cross section of the sample 105 existing further inside, the milling at the sample protrusion amount h to the extent that the sample 105 is not affected by heat is repeated, and thus it is possible to perform sample processing of a target amount with high throughput while reducing the influence of heat application on the sample 105.

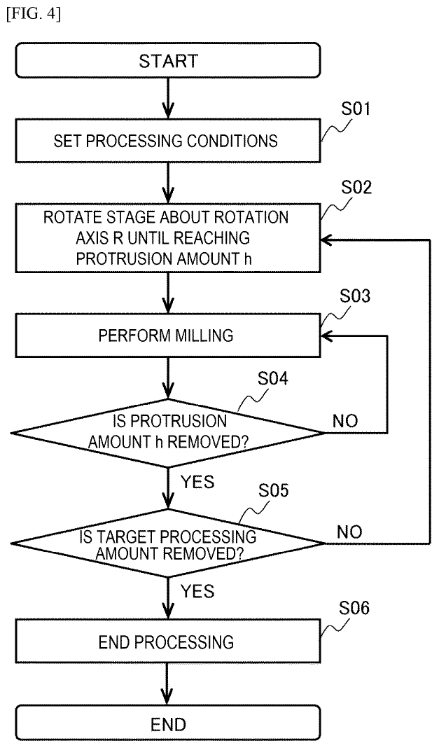

The flowchart shown in FIG. 4 illustrates a series of operations from the start to the end of the sample processing in the ion milling device 100 according to Embodiment 1. Each operation will be described in detail.

S01: Sample processing conditions of the ion milling device 100 are set. The sample processing conditions include, in addition to milling conditions such as settings of the acceleration voltage, the discharge voltage, and the supply amount of the argon gas for the ion source 101, processing conditions such as the sample protrusion amount h at the time of performing the milling and the processing amount for performing the cross-section processing. However, since a desirable magnitude of the sample protrusion amount h depends on the material, it is desirable that the control unit 109 registers in advance the magnitude of the sample protrusion amount h according to the material to enable selection of the sample protrusion amount h according to the material to be processed.

The sample 105 is placed on the sample support 104 with the end surface P₁ serving as the processing surface of the sample 105 and the end surface P₂ of the shielding plate 106 aligned. After the alignment mechanism 107 adjusts the position of the sample stage 102 in advance such that the rotation axis R, the swing axis S, and the ion beam central axis B intersect at one point, the cross-section processing of the sample 105 is started. The subsequent operations are executed automatically by the control unit 109.

S02: The control unit 109 rotates the sample stage 102 about the rotation axis R by using the sample stage drive mechanism 103, and stops the rotation of the sample stage 102 when the sample protrusion amount h is reached.

S03: The milling is performed based on the milling conditions set in step S01.

S04: Whether the set sample protrusion amount h set in step S01 is removed is confirmed. If the portion of the sample protruding from the shielding plate as viewed from the ion source is removed, the sample is stopped from being irradiated with the ion beam. The determination in this step may be performed based on, for example, whether a predetermined time has elapsed since the start of the milling, or may be performed based on the amount of microparticles generated in the milling.

S05: Whether a target processing amount is removed is confirmed. For example, the control unit 109 calculates the number of times of repetition of the milling of the sample protrusion amount h required for obtaining the target processing amount, and makes the determination based on whether the required number of times of repetition are performed. When the target processing amount is not reached, the sample stage 102 is rotated about the rotation axis R again to obtain the sample protrusion amount h (S02), and the milling is executed (S03).

S06: When the target processing amount is reached, the processing is ended.

### Embodiment 2

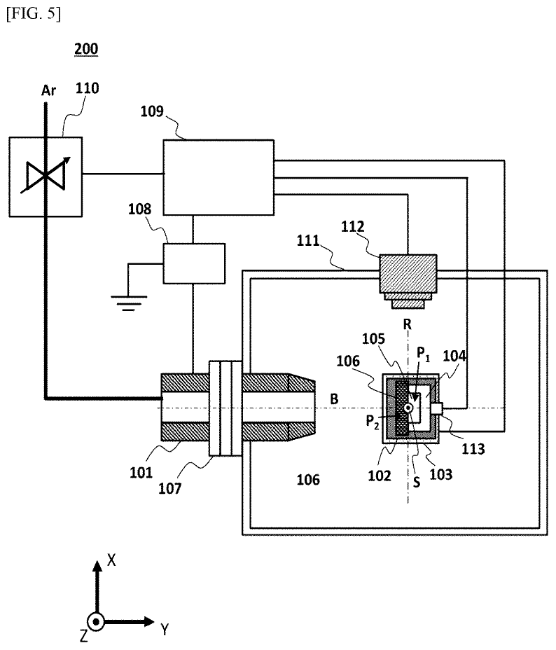

FIG. 5 is a schematic diagram illustrating, from an upper side, main parts of an ion milling device 200 according to Embodiment 2. Also in FIG. 5, a vertical direction is indicated as a Z direction, and the same components as those of the ion milling device 100 according to Embodiment 1 are denoted by the same reference signs, and a repeated description thereof is omitted. In FIG. 5, the sample stage 102 is in a posture in which the end surface P₁ serving as a processing surface of a sample is directed in the Z direction.

The ion milling device 200 includes a camera 112 disposed in an X direction from the sample stage 102 in order to monitor the sample protrusion amount h of the sample 105 with respect to the shielding plate 106, and a thermocouple 113 serving as a temperature sensor for measuring a temperature of the sample 105. By monitoring the sample 105 during milling, the ion milling device 200 can more reliably prevent the sample 105 from being thermally damaged by the milling.

Specifically, a maximum sample temperature Ti is set in advance, and when the temperature of the sample 105 detected by the thermocouple 113 exceeds the maximum sample temperature Ti, the emission of the ion beam from the ion source 101 is automatically stopped. The rotation of the sample stage 102 about the rotation axis R by the sample stage drive mechanism 103 which determines the sample protrusion amount h is also controlled while monitoring with the camera 112.

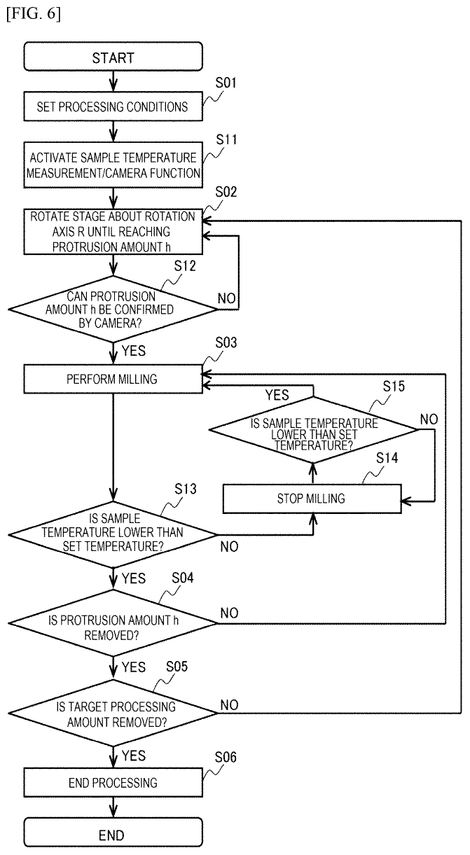

The flowchart shown in FIG. 6 illustrates a series of operations from the start to the end of sample processing in the ion milling device 200 according to Embodiment 2. The same steps as those in the flowchart in FIG. 4 are denoted by the same reference signs, and a repeated description thereof is omitted. Steps added in the flowchart of Embodiment 2 will be mainly described.

S11: After the processing condition setting (step S01), the control unit 109 activates a sample temperature measuring function of the thermocouple 113 and a monitoring function of the camera 112 (S11). It is assumed that the maximum sample temperature Ti is set in advance in the processing condition setting (S01). It is desirable that the control unit 109 registers in advance the magnitude of the maximum sample temperature Ti according to the material to enable selection of the maximum sample temperature Ti according to the material to be processed.

S12: The sample stage 102 is rotated about the rotation axis R until the sample protrusion amount h is reached (step S02), and whether the sample protrusion amount is correctly adjusted is confirmed based on an image captured by the camera 112 (S12). If the adjustment fails, the control unit 109 controls the sample stage drive mechanism 103 to eliminate a control error and rotates the sample stage 102 to adjust a position of the sample 105.

S13 to S15: During the milling (step S03), control is performed using the thermocouple 113 such that the sample 105 is not subjected to excessive heat application. Therefore, when the sample temperature is equal to or higher than the set maximum sample temperature Ti, the supply of the voltage from the high-voltage power supply 108 to the ion source 101 is temporarily stopped, and the emission of the ion beam from the ion source 101 is stopped (step S14). When it is confirmed that the temperature measured by the thermocouple 113 is lower than the maximum sample temperature Ti by stopping the emission of the ion beam (YES in step S15), the milling is resumed.

The camera 112 may be used for determining whether the sample protrusion amount h is removed (step S04).

Although the invention made by the present inventor has been specifically described based on embodiments, the invention is not limited to the embodiments described above, and various modifications can be made without departing from the gist of the invention. For example, in order to align the ion beam central axis B with the rotation axis R and the swing axis S, a mechanism that can move in the X direction, a Y direction, and the Z direction may be provided on the sample stage 102, instead of providing the alignment mechanism 107. In this case, the position of the sample stage 102 is adjusted instead of moving the ion source 101, whereby an axial position can be adjusted.

### REFERENCE SIGNS LIST

100, 200: ion milling device
101: ion source
102: sample stage
103: sample stage drive mechanism
104: sample support
105: sample
106: shielding plate
107: alignment mechanism
108: high-voltage power supply
109: control unit
110: supply gas control unit
111: sample chamber
112: camera
113: thermocouple
201: first cathode
202: second cathode
203: anode
204: permanent magnet
205: acceleration electrode
206: gas piping
301: front view
302: side view

1. An ion milling device comprising:
an ion source configured to emit an ion beam;
a sample stage configured to hold a sample;
a shielding plate configured to shield the sample from the ion beam and disposed such that an end surface thereof and an end surface serving as a processing surface of the sample are aligned with each other;
a sample stage drive mechanism configured to rotate the sample stage with a boundary between the end surface of the shielding plate and the end surface of the sample as a rotation axis; and
a control unit, wherein
a relative position between the ion source and the sample stage is adjusted such that a central axis of the ion beam intersects the rotation axis, and
the control unit rotates the sample stage about the rotation axis using the sample stage drive mechanism until a sample protrusion amount at which the sample protrudes from the shielding plate as viewed from the ion source reaches a predetermined magnitude, and thereafter performs milling on the sample by irradiating the sample with the ion beam from the ion source.

2. The ion milling device according to claim 1, wherein
the control unit stops irradiating the sample with the ion beam when a portion of the sample protruding from the shielding plate as viewed from the ion source is removed, rotates the sample stage again about the rotation axis using the sample stage drive mechanism until the sample protrusion amount at which the sample protrudes from the shielding plate as viewed from the ion source reaches the predetermined magnitude, and thereafter performs the milling on the sample by re-irradiating the sample with the ion beam from the ion source.

3. The ion milling device according to claim 2, wherein
the control unit
stops irradiating the sample with the ion beam when a portion of the sample protruding from the shielding plate as viewed from the ion source is removed, and
ends cross-section processing of the sample when it is determined that a target processing amount is removed from the sample.

4. The ion milling device according to claim 1, wherein
the control unit sets the predetermined magnitude according to a material of the sample.

5. The ion milling device according to claim 1, wherein
the sample stage drive mechanism swings the sample and the shielding plate in a predetermined angular range about a swing axis orthogonal to the rotation axis, and
the relative position between the ion source and the sample stage is adjusted such that the rotation axis, the swing axis, and the central axis of the ion beam intersect at one point.

6. The ion milling device according to claim 1, further comprising:
a movable mechanism configured to adjust a position of the ion source.

7. The ion milling device according to claim 1, further comprising:
a movable mechanism configured to adjust a position of the sample stage.

8. The ion milling device according to claim 1, further comprising:
a camera, wherein
the camera is disposed such that an optical axis thereof is in parallel with the rotation axis, and
the control unit confirms, based on an image captured by the camera, that the sample protrusion amount at which the sample protrudes from the shielding plate as viewed from the ion source is the predetermined magnitude.

9. The ion milling device according to claim 1, further comprising:
a temperature sensor configured to measure a temperature of the sample, wherein
the control unit stops irradiating the sample with the ion beam when the temperature of the sample detected by the temperature sensor is equal to or higher than a predetermined temperature.

10. The ion milling device according to claim 9, wherein
the temperature sensor is a thermocouple.
